(19) United States
(12) Patent Application Publication
(10) Pub. No.: US 2024/0244758 A1
(43) Pub. Date: Jul. 18, 2024

(54) Wire Dispensing Device

(71) Applicant: Sciperio, Inc, Orlando, FL (US)

(72) Inventors: Miles Radliff, Orlando, FL (US); Kenneth H. Church, Orlando, FL (US); Paul I. Deffenbaugh, Orlando, FL (US)

(73) Assignee: Sciperio, Inc, Orlando, FL (US)

(21) Appl. No.: 18/403,240

(22) Filed: Jan. 3, 2024

Related U.S. Application Data
(60) Provisional application No. 63/480,074, filed on Jan. 16, 2023.

(51) Int. Cl. H05K 3/10; B65H 35/00; H05K 1/02

(52) U.S. Cl. CPC H05K 3/103; B65H 35/0013; H05K 1/0298; B65H 35/008; B65H 2701/36

(57) ABSTRACT

A system for manufacturing electronics includes a wire dispensing tool head, a motion system for positioning a dispensing head around a part being fabricated, a spool for holding spooled wire, a feed mechanism operatively connected between the spool and the wire dispensing tool head for feeding the wire from the spool to the wire dispensing tool head, a cutting system configured to cut the wire after dispensement from the wire dispensing tool head, and a control system operatively connected to the motion system.

### RELATED APPLICATION

This application claims priority to U.S. Provisional Patent Application No. 63/480,074, filed Jan. 16, 2023, hereby incorporated by reference in its entirety.

### FIELD OF THE INVENTION

The present disclosure relates to additive manufacturing. More particularly, but not exclusively, the present disclosure relates to manufacturing which involves placement of wires, fibers, or filaments.

BACKGROUND

In various types of additive manufacturing and especially in additive manufacturing of electronic printed structures, conductive ink may be dispensed in order to provide conductive circuit traces or other structures. Similarly, dielectric materials may be dispensed to create dielectric structures or layers. Yet despite these tools and techniques there are various limitations which may be more apparent in particular applications or use. In particular, there are situations where it would be advantageous to place wires, fibers, or filaments as part of the manufacturing process and in an automated manner in order to remove limitations on the type of object being manufactured and its physical characteristics especially in the context of printed electronic structures and/or additively manufactured conformal electronics. Therefore, what is needed are new and improved methods and systems for additive manufacturing.

SUMMARY

Therefore, it is a primary object feature, or advantage of the present disclosure to improve over the state of the art.

Another object, feature, or advantage is to provide a device for use in manufacturing of printed electronic structures and/or additively manufactured conformal electronics.

It is a further object, feature, or advantage to provide for placement of wires, fibers, or filaments as a part of the manufacturing process.

It is a still further object, feature, or advantage of the present disclosure to provide a device for dispensing, cutting, and welding into place controlled amounts of wire, fibers, or filaments.

It is a still further object, feature, or advantage of the present disclosure to provide a solution that is versatile in its use.

Another object, feature, or advantage is to provide a wire dispensing device which may be integrated with other fabrication methods.

Yet another object, feature, or advantage is to provide a wire dispensing device suitable for depositing wire which allows for interconnection with other circuit elements.

A still further object, feature, or advantage is to provide a wire dispensing device which may wind wire around a pin or otherwise.

Another object, feature, or advantage is to provide a wire dispensing device which may be used in creating multilayer circuit boards.

Yet another object, feature, or advantage is to provide a wire dispensing device which may be used in positioning wire in free space.

One or more of these and/or other objects, features, or advantages of the present disclosure will become apparent from the specification and claims that follow. No single aspect need provide each and every object, feature, or advantage. Different aspects may have different objects, features, or advantages. Therefore, the present disclosure is not to be limited to or by any objects, features, or advantages stated herein.

According to one aspect a wire dispensing device is provided which capable of dispensing various diameters of wire, optical fibers, carbon fiber filaments, and other solid materials. The wire dispensing device is intended to be used in the field of printed electronic structures and/or additively manufactured conformal electronics. The wire dispensing device has the potential to increase the performance of printed electronic circuits. The wire dispensing device may also be used as a winding arm to create electromagnetic coils in printed electronic structures.

According to some implementations, a system for manufacturing may include a motion system for positioning a wire dispensing head around a part being fabricated. The system may also include a spool for holding spooled wire. The system may furthermore include a feed mechanism operatively connected between the spool and the wire dispensing tool head for feeding the wire from the spool to the wire dispensing tool head. The system may further include a cutting system configured to cut the wire after dispensement from the wire dispensing tool head. The system may include a control system operatively connected to the motion system. Other embodiments of this aspect include corresponding computer systems, apparatus, and computer programs recorded on one or more computer storage devices, each configured to perform the actions of the methods.

The described implementations may also include one or more of the following features. The control system may be configured to provide pre-travel and post-travel movements to assist in placing the wire. The control system may be configured to provide cut length compensation. The control system may be configured to control lateral speed of the dispensing at least partially based on a feed speed of the wire. The system may include a wire placement system configured to place the wire. The system may include a plurality of tool heads where a first of the tool heads is the wire dispensing tool head and where a second of the tool heads is selected from a set having of a fused filament fabrication (FFF) tool head, a microdispensing tool head, a milling tool head, a pick and place tool head, and a spray tool head. The wire may be selected from a set having a conductive wire, a filament, and a fiber. Implementations of the described techniques may include hardware, a method or process, or a computer tangible medium.

Some implementations herein relate to a method. For example, a method may include providing system for manufacturing electronics having a wire dispensing tool head, a motion system for positioning a dispensing head around a part being fabricated, a spool for holding spooled wire, a feed mechanism operatively connected between the spool and the wire dispensing tool head for feeding the wire from the spool to the wire dispensing tool head, a cutting system configured to cut the wire after dispensement from the wire dispensing tool head, and a control system operatively connected to the motion system. The method may also include a step of controlling the wire dispensing tool head with the control system to position the wire dispensing head using the motion system to dispense a length of the wire in a desired position of the part being fabricated. The method may furthermore include dispensing from the wire dispensing tool head the length of the wire at the desired position of the part being fabricated. The method may in addition include cutting the length of the wire from a feed of wire from the spooled wire. Other embodiments of this aspect include corresponding computer systems, apparatus, and computer programs recorded on one or more computer storage devices, each configured to perform the actions of the methods.

The described implementations may also include one or more of the following features. The method may include soldering the length of the wire to form an interconnection within the part being fabricated. The length of wire may be dispensed in a shape of a coil. The length of wire may be dispensed in a shape of an antenna pattern having at least one curve. The desired position may be s within a material having dielectric properties and the method further may include solidifying the material after the dispensing of the wire. The cutting may be performed using a blade. The cutting may be performed using a laser. The part being fabricated may include a multilayer circuit board. Implementations of the described techniques may include hardware, a method or process, or instructions stored on a computer readable non-transitory medium.

Some implementations herein relate to a method. For example, the method may include applying a layer of material. The method may also include controlling a wire dispensing tool head associated with a motion system using a control system to position the wire dispensing head using the motion system to dispense a length of the wire in a desired position within the layer of material. The method may furthermore include dispensing from the wire dispensing tool head the length of the wire at the desired position of the within the layer of material. The method may in addition include cutting the length of the wire from a feed of wire from the spooled wire. Other embodiments of this aspect include corresponding computer systems, apparatus, and computer programs recorded on one or more computer storage devices, each configured to perform the actions of the methods.

The described implementations may also include one or more of the following features. The material may include a dielectric material with sufficient viscosity to hold the wire in place. The material may include a dielectric material and an adhesive material. The method may be repeated in order to form a multilayer circuit board. Implementations of the described techniques may include hardware, a method or process, or instructions stored on a computer readable non-transitory medium.

### BRIEF DESCRIPTION OF THE DRAWINGS

Illustrated aspects of the disclosure are described in detail below with reference to the attached drawing figures, which are incorporated by reference herein.

FIG. 1 is a block diagram providing an overview of a system for dispensing wire.

FIG. 2 is a perspective view of a device for dispensing wire.

FIG. 3 is another perspective view showing the device of FIG. 2 in addition to a bracket for mounting a spool.

FIG. 4 illustrates a spool mounted to the bracket of FIG. 3.

FIG. 5 illustrates one example of a wire feed mechanism of the device.

FIG. 6 illustrates one example of cutting wire with a knife or blade.

FIG. 7 illustrates one example of cutting wire with a laser.

FIG. 8 is a diagram of another embodiment of a system which includes the wire dispensing device.

FIG. 9 illustrates one example of a method.

FIG. 10 illustrates one example of a method of constructing a multilayer circuit board using a device configured to cut and dispense wire.

### DETAILED DESCRIPTION

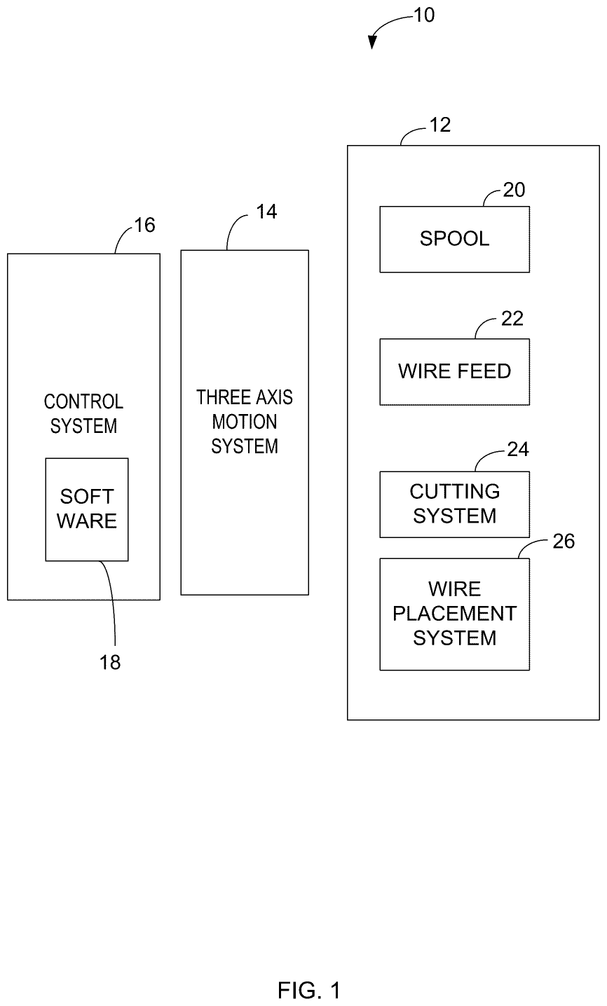

FIG. 1 is a block diagram illustrating one example of a system or device 10. A device 10 is shown which dispenses, cuts, and welds into place wire including fibers, or filaments. As used herein the term “wire” is used to include wires, fibers, filaments, including metallic wires, conductive wires, and the like. A three axis motion system 14 is shown which the device 10 is mounted to and which is used to position the device 10. A control system 16 is also shown which provides for positioning the device 12 around a part being fabricated. The control system 16 may include software 18 which controls the positioning. The software may also provide pre-travel and post travel movements to better place the wire. The software may also provide for cut length compensation.

The device 12 includes a spool 20, a wire feed system 22, a cutting system 24, and a wire placement system 26 which will be described in further detail. In operation, the different systems operate together as controlled by the control system 16 in order to dispense, cut, and weld into place controlled amounts of wire, fibers, or filaments.

The system 10 may be used to dispense various diameters of conductive wire, various widths of flat conductive ribbon, glass fiber filaments, and carbon fiber filaments. In some embodiments, a spool 20 of wire is loaded into the system. The spool of wire can be positioned on the device 12 or may be located separately and the fed to the device 12 through free space or in a guide tube such as a tube made of a slippery material such as Polytetrafluoroethylene (PTFE) plastic. Tension may be maintained on the wire to prevent the spool from becoming sprung. Tensioning may be provided in any number of ways including through use of a tensioning mechanism. The tensioning mechanism may be motor driven with constant current/torque. The tensioning mechanism may be a brake such as felt or another high friction material. The tensioning mechanism may be a spring such as a wave spring. Of course, other types of tensioning mechanisms may be used.

The spool system 20 may also include a loading mechanism to allow the spool to be easily changed when empty or if a wire of a different diameter or type is to be used. In some embodiments, an automated spool changer may be used which is controlled by the control system 16. In some embodiments, an automated wire-rethreading system may also be used.

A wire feed system 22 is shown. In operation, a spool of wire may be fed into a tractor wheel which pushes the wire through the device 12 and out. The tractor wheel may have teeth cut into it such as a gear or hobbed gear. The tractor wheel may be rubberized or have a tire on it. The tractor wheel may be single drive or dual drive or have any number of drive wheels. In some embodiments, guides may be fitted to guide the wire into the drive gear and out of the exit from the drive gear to prevent the wire from moving sideways and to prevent misalignment.

A cutting system is shown. In some embodiments a cutting mechanism may be used to cut the wire at the surface. In some embodiments, a laser may be used to cut the wire. In other embodiments a knife/knife arrangement may be used to cut the wire. In other embodiments a knife/anvil arrangement may be used to cut the wire. In other embodiments, a sheer (or set of shears) may be used to cut the wire. In some embodiments, an electric arc may be used to cut the wire.

A wire placement system is shown. Wire may be pressed into the surface or laid along the top of the surface. In some embodiments, wire may be pressed into the surface using a presser foot much like a sewing machine. In some embodiments, wire can be heat-set into the surface. Where heat is used, heat (from the heat-set) may be from an ohmic heater, a piezoelectric transducer, or a laser. In some embodiments, a needle, nozzle, ceramic tip, or other pointy device can emit the wire and introduce that wire onto or into the surface. Thus, the device 12 allows for wire to be dispensed in various ways including being dispensed into free space or wound around objects.

Prior to or after dispensing, interconnects between dispensed wire and other structures or features may be formed in any number of ways. The dispensed wire may make connections to electrical components or to existing electrical traces or circuit components. A laser may be used to weld the wire. Conductive inks may also be applied to the wire to form connections. Ultrasonic welding may also be used to weld the wire. The wire may also terminate in free space without an interconnection. Thus, it is contemplated that any number of different types of interconnects may be present on either end of the wire.

The wire dispensing device may be coordinated with other systems as a part of an additive manufacturing process. In some embodiments, the device 12 or at least portions thereof are mounted on a head which may be positioned by the control system 16. In some embodiments, the control system 16 may control other heads with different types of tools or be in operative communication with other control systems for controlling other heads with other types of tools.

For example, in some embodiments the device 12 may be used in conjunction with a spray head. The spray head may provide for wide area coverage of an epoxy or other material with adhesive properties. Then the device 12 may dispense wire which adheres to the epoxy or other substance.

In other applications, the device 12 can be used to create small feature interconnects with circuits, to create low power circuit traces with small diameter wire. In other applications, the device 12 may be used to improve conductivity of materials by applying wire and the dispensing conductive ink. In still other applications, the wire may be dispensed into troughs or around pins to wind electromagnetic coils or patch antennas.

In another example of a use case, pattern wide area coverage or fine feature patterns of a dielectric serve as an electrical dielectric layer. The device 12 may then lay wire in the dielectric to fabricate a circuit. The dielectric may be viscous enough to hold the wire in place, and including curved patterns that the device 12 will traverse leaving the wire in diverse shapes. The dielectric may be a combination of materials with exceptional dielectric properties and a tacky or sticky attribute to hold the wire in place. The dielectric may set, cure, polymerize, harden with heat or laser light (photonic). The combination of patterned dielectric and wires in a layer by layer fashion may create a multilayer circuit board.

Thus, the system has a number of use cases in additive manufacturing especially combined with other tools. Examples of other tools which may be used, includes spray heads, dispensing heads, pick and place systems, etc.

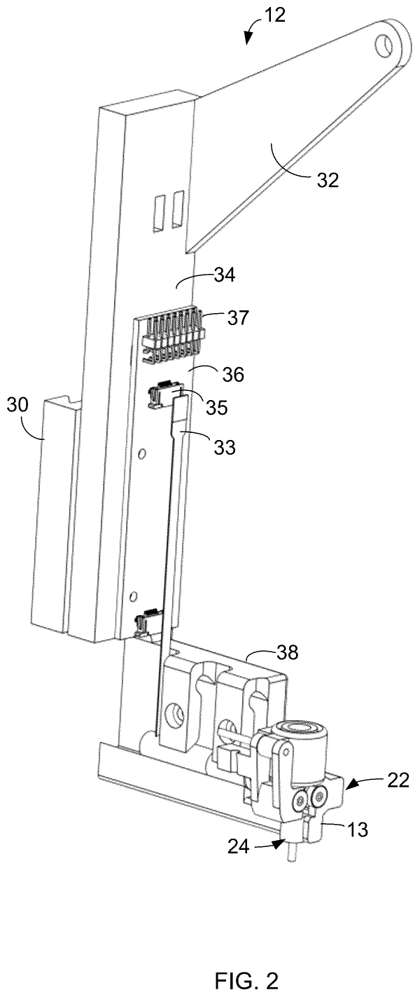

The system shown in FIG. 1 may be implemented in a number of different ways. FIG. 2 through FIG. 7 illustrate a specific embodiment; however, it is to be understood that what is illustrated and described is merely representative and various options, variations, and alternatives are contemplated.

FIG. 2 illustrates one example of the device 12 with a dispensing head 13. A spool arm 32 is shown for supporting a spool of wire (not shown in FIG. 2). A main body 34 is shown with a mounting slide 30 operatively connected to the main body 34 to allow for mounting of the device 12 to a three axis motion system. An arm 38 extends outwardly and generally orthogonally from the main body 34 although different configurations are contemplated. In some embodiments it may be advantageous to have the spool mounting arm 32 and the arm 38 aligned in a manner to limit the required distance of travel of wire on the spool arm 32 to the arm 38 and to the wire feed mechanism 22.

A circuit board 36 is shown mounted to the main body 34. A header 37 is shown which may be used to connect the circuit board to the control system. A cable 33 may be present which is used to connect electronics and electro-mechanical parts mounted on the arm 38 to the port 35 which may in turn electrically connect those connections to the header 37. Of course, other types of electrical connections may be made.

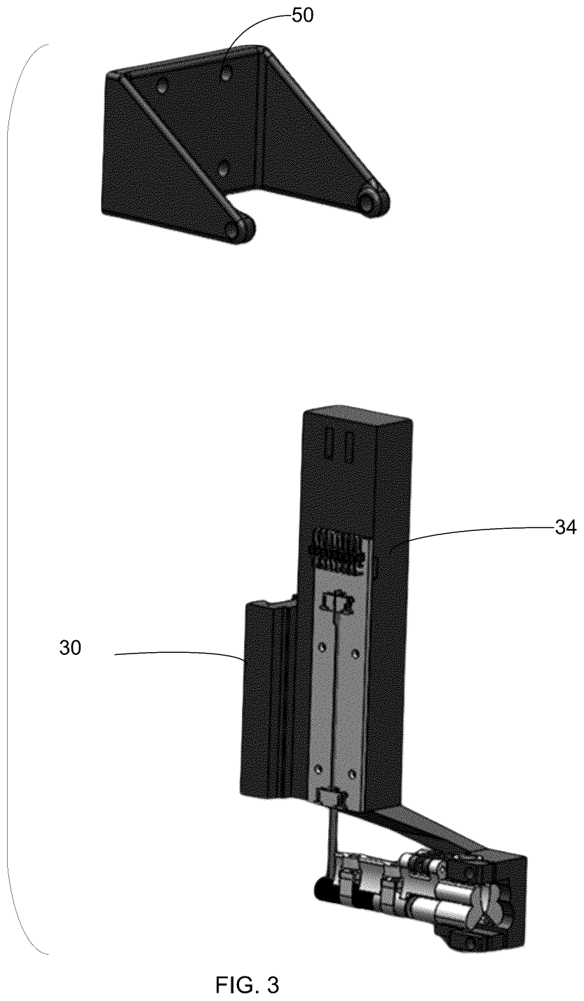

FIG. 3 illustrates another perspective view of the device. A spool mounting bracket 50 is shown which may be used to mount a spool of wire (not shown).

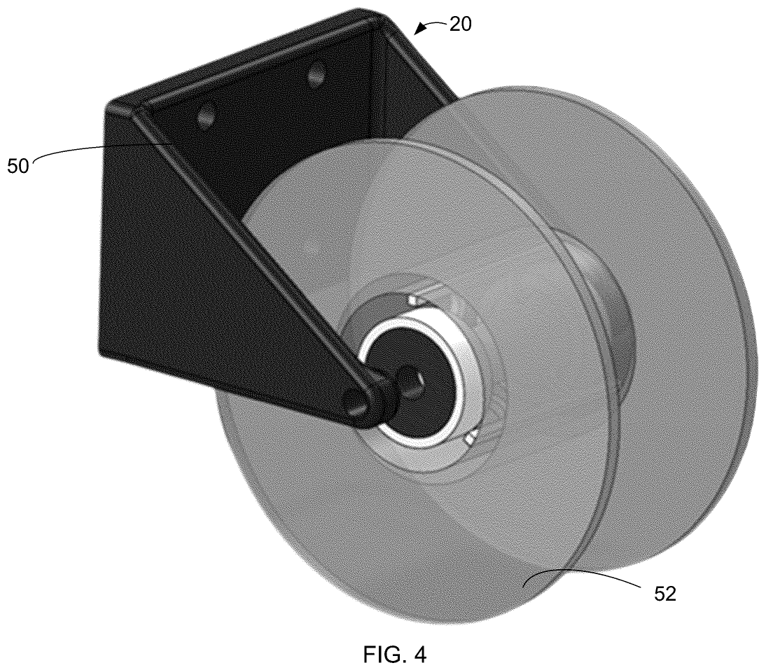

FIG. 4 illustrates the spool mounting bracket 50 with a spool 52 mounted to the spool mounting bracket 50.

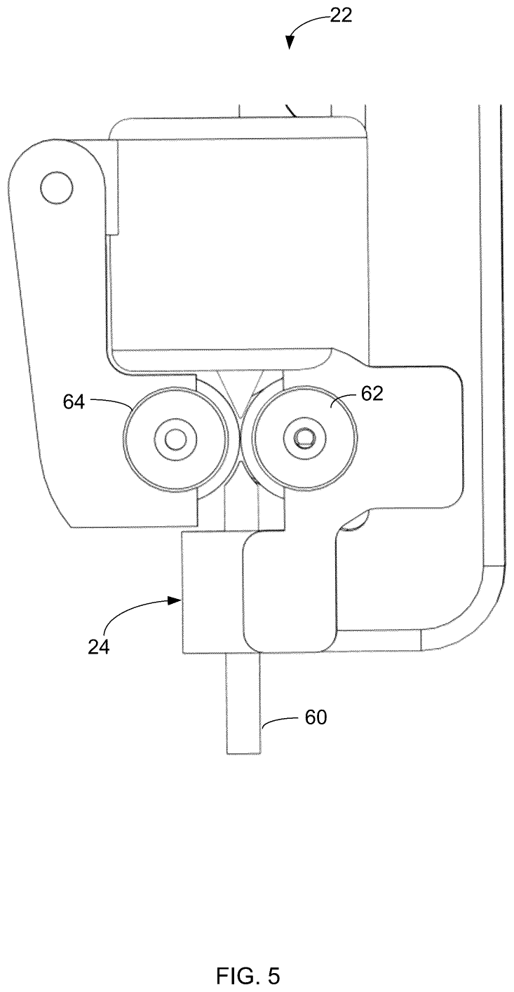

FIG. 5 illustrates one example of a wire feed mechanism 22 of the device. As shown in FIG. 5, opposing rollers 62, 64 are provided which engage the wire. Tension between the rollers 62, 64 may be set based on the diameter of the wire or other factors.

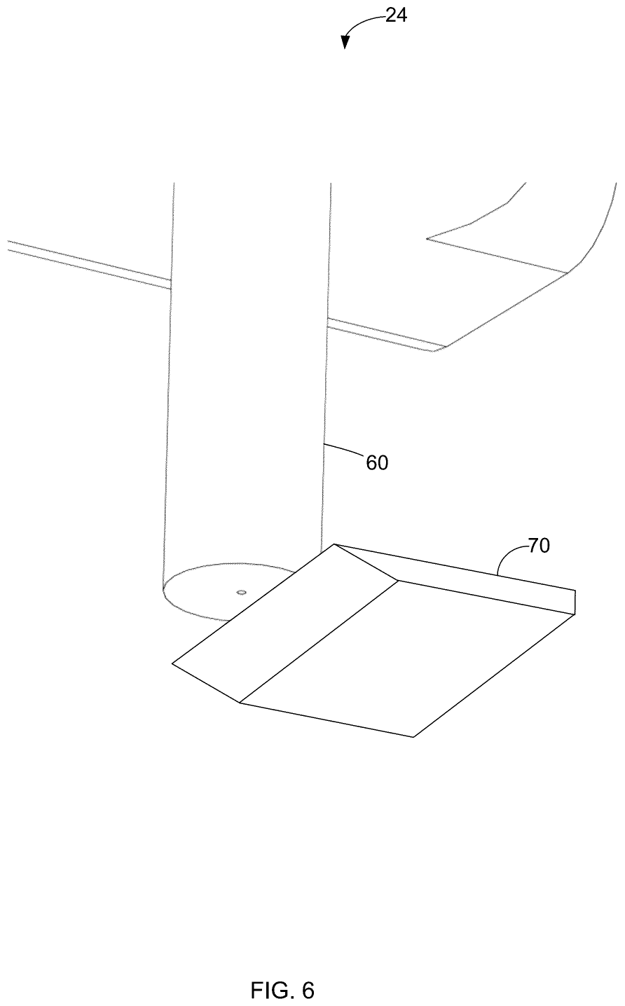

FIG. 6 illustrates one example of cutting wire with a knife or blade 70 used to cut the wire 60. Thus, wire may be dispensed into desire locations or positions and then cut.

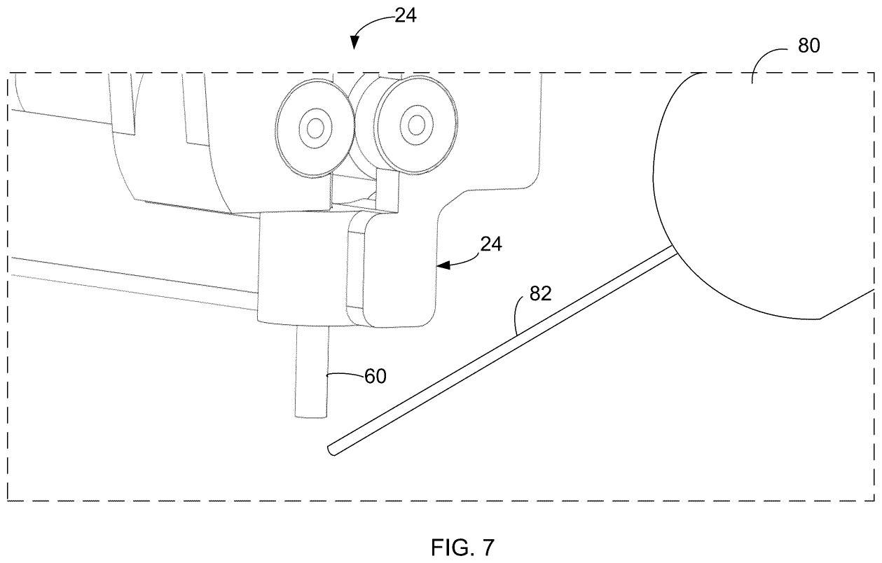

FIG. 7 illustrates one example of cutting wire 60 with a laser 80 having a laser beam 82 for cutting. Where a laser is used, the laser 80 may also be used to solder the wire to other electronic components.

It is to be further understood that any number of different sensors may be present such as sensors used to sense the position of the wire, the speed of the file, the placement of the wire, the tension on the wire, or other parameters. Sensors may also be used to sense temperature of the wire such as when the wire is being soldered or otherwise.

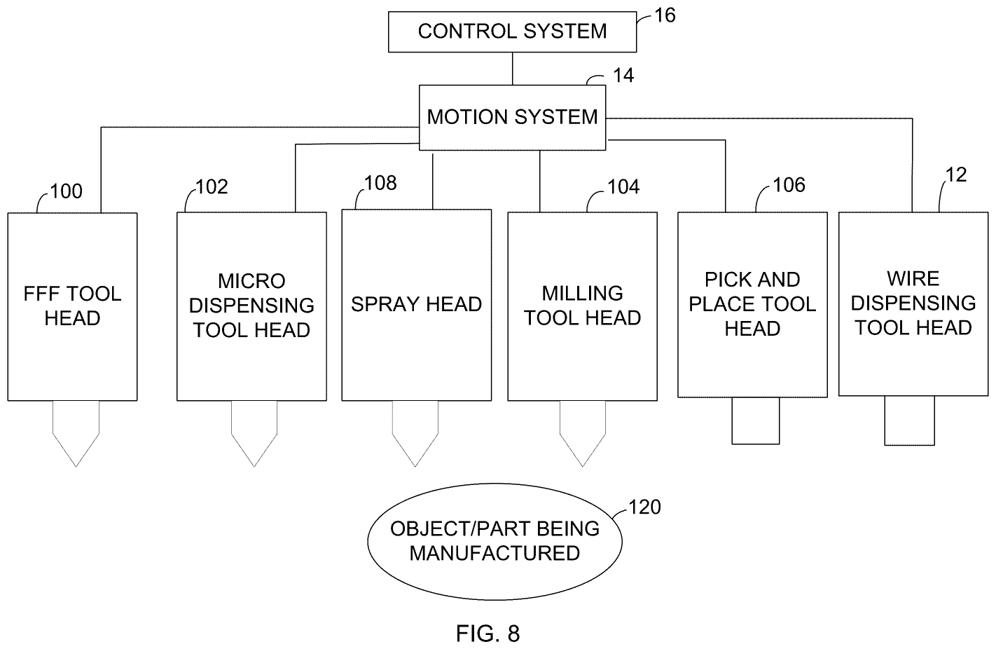

FIG. 8 is a diagram of another embodiment of a system which includes the wire dispensing device 12. A motion system 14 is shown which control positioning of the wire dispensing device relative to an object or part being manufactured 120. Portions of the motion system 14 may be configured to control other types of tool heads or devices used in manufacturing. The motion system 14 may include multiple different motion platforms. Other types of tool heads which may be controlled may include a fused filament fabrication (FFF) tool head 100, a microdispensing tool head 102, a milling tool head 104, a pick and place tool head 106, and a spray head 108. It is to be understood that different applications may use fewer tool heads then shown. In some applications there may be multiple tool heads which perform the same function such as used for different materials. The system shown including the wire dispensing device 12 may be used to manufacture an object or part 120. The object or part 120 may be of any number of different sizes, shapes, materials, including with complex circuitry, multiple layers, and number of the different features described herein. The object being shown 120 is represented as a spheroid, to emphasize that it need not be planar in nature. Similarly, any surface of the structure or object being manufactured which may considered as a substrate for subsequent operations need not be planar but may be conformal or of any number of other shapes or complex geometries.

The wire dispensing device 12 may be used in conjunction with a system which includes any or all of these different tool heads during manufacturing of an object or part being manufactured 120. It should be appreciated that the addition of the wire dispensing device 12 accommodates numerous different situations where it is useful or advantageous to include wires including for coils, antennas, interconnects, or otherwise. It should also be appreciated that a spool changer may be used to change out the spool of wire to accommodate different types of wires or different diameters of wires. In some embodiments, more than one wire dispensing device 12 may be used.

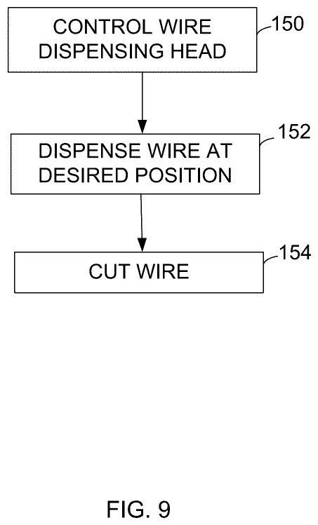

FIG. 9 illustrates one example of a method. The method may be performed using a system for manufacturing electronics which includes a wire dispensing tool head, a motion system for positioning a dispensing head around a part being fabricated, a spool for holding spooled wire, a feed mechanism operatively connected between the spool and the wire dispensing tool head for feeding the wire from the spool to the wire dispensing tool head, a cutting system configured to cut the wire after dispensement from the wire dispensing tool head, and a control system operatively connected to the motion system. The method may include in step 150, controlling the wire dispensing tool head with the control system to position the wire dispensing head using the motion system to dispense a length of the wire in a desired position of the part being fabricated. The method may include in step 152, dispensing from the wire dispensing tool head the length of the wire at the desired position of the part being fabricated. The method may include cutting the wire in step 154.

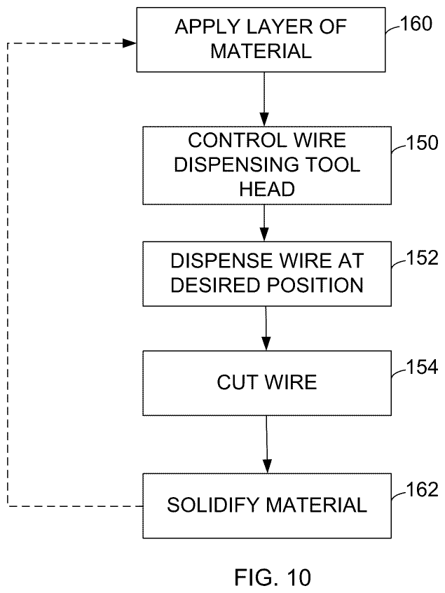

FIG. 10 illustrates another example of a method of constructing a multilayer circuit board using a device configured to cut and dispense wire. The method may include in step 160, applying a layer of material. In step 150, the method may include controlling a wire dispensing tool head associated with a motion system using a control system to position the wire dispensing head using the motion system to dispense a length of the wire in a desired position within the layer of material. In step 152, the method may include dispensing from the wire dispensing tool head the length of the wire at the desired position of the within the layer of material. In step 154, the method may include cutting the length of the wire from a feed of wire from the spooled wire. In step 162, the method may further include hardening or solidifying the material with the wire positioned at a desired location within the material. This hardening, solidifying, curing, photocuring, setting, or other type of solidifying may be performed in any number of ways such as by applying light, heat, or otherwise. Thus, in this manner a layer of a circuit board may be formed. The process may be repeated by returning to step 160 and repeating the process in order to construct a multilayer circuit board. The material may be a dielectric material with sufficient viscosity to hold the wire in place. The specific viscosity required will depend upon the size, geometry, and composition of the wire. The material may further include a dielectric material and an adhesive material.

The disclosure is not to be limited to the particular aspects described herein. In particular, the disclosure contemplates numerous variations in the structure of the wire dispensing device, its configuration, and control as well as in the manner which the wire dispensing device is combined with additional fabrication tools and used in specific applications such as those used in creating electronic circuits or objects which include electronic circuits. The foregoing description has been presented for purposes of illustration and description. It is not intended to be an exhaustive list or limit any of the disclosure to the precise forms disclosed. It is contemplated that other alternatives or exemplary aspects are considered included in the disclosure. The description is merely examples of aspects, processes, or methods of the disclosure. It is understood that any other modifications, substitutions, and/or additions can be made, which are within the intended spirit and scope of the disclosure.

What is claimed is:

1. A system for manufacturing electronics comprising:
a wire dispensing tool head;
a motion system for positioning a dispensing head around a part being fabricated;
a spool for holding spooled wire;
a feed mechanism operatively connected between the spool and the wire dispensing tool head for feeding the wire from the spool to the wire dispensing tool head;
a cutting system configured to cut the wire after dispensement from the wire dispensing tool head; and
a control system operatively connected to the motion system.

2. The system of claim 1 wherein the control system is configured to provide pre-travel and post-travel movements to assist in placing the wire.

3. The system of claim 1 wherein the control system is configured to provide cut length compensation.

4. The system of claim 1 wherein the control system is configured to control lateral speed of the dispensing at least partially based on a feed speed of the wire.

5. The system of claim 1 further comprising a wire placement system configured to place the wire.

6. The system of claim 1 further comprising a plurality of tool heads wherein a first of the tool heads is the wire dispensing tool head and wherein a second of the tool heads is selected from a set consisting of a fused filament fabrication (FFF) tool head, a microdispensing tool head, a milling tool head, a pick and place tool head, and a spray tool head.

7. The system of claim 1 wherein the wire is selected from a set consisting of a conductive wire, a filament, and a fiber.

8. A method for manufacturing electronics comprising:
providing system for manufacturing electronics comprising a wire dispensing tool head, a motion system for positioning a dispensing head around a part being fabricated, a spool for holding spooled wire, a feed mechanism operatively connected between the spool and the wire dispensing tool head for feeding the wire from the spool to the wire dispensing tool head, a cutting system configured to cut the wire after dispensement from the wire dispensing tool head, and a control system operatively connected to the motion system;
controlling the wire dispensing tool head with the control system to position the wire dispensing head using the motion system to dispense a length of the wire in a desired position of the part being fabricated;
dispensing from the wire dispensing tool head the length of the wire at the desired position of the part being fabricated; and
cutting the length of the wire from a feed of wire from the spooled wire.

9. The method of claim 8 further comprising soldering the length of the wire to form an interconnection within the part being fabricated.

10. The method of claim 8 wherein the length of wire is dispensed in a shape of a coil.

11. The method of claim 8 wherein the length of wire is dispensed in a shape of an antenna pattern having at least one curve.

12. The method of claim 8 wherein the desired position is within a material having dielectric properties and wherein the method further comprises solidifying the material after the dispensing of the wire.

13. The method of claim 8 wherein the cutting is performed using a blade.

14. The method of claim 8 wherein the cutting is performed using a laser.

15. The method of claim 8 wherein the part being fabricated comprises a multilayer circuit board.

16. A method of constructing a multilayer circuit board using a device configured to cut and dispense wire, the method comprising steps of:
applying a layer of material;
controlling a wire dispensing tool head associated with a motion system using a control system to position the wire dispensing head using the motion system to dispense a length of the wire in a desired position within the layer of material;
dispensing from the wire dispensing tool head the length of the wire at the desired position within the layer of material; and
cutting the length of the wire from a feed of wire from spooled wire.

17. The method of claim 16 wherein the material comprises a dielectric material with sufficient viscosity to hold the wire in place.

18. The method of claim 16 wherein the material comprises a dielectric material and an adhesive material.

19. The method of claim 16 further comprising hardening the layer of the material with the wire in place.

20. A method comprising repeating the steps of claim 16 to create a multilayer circuit board.
